(19) United States
(12) Patent Application Publication
(10) Pub. No.: US 2007/0054439 A1
(43) Pub. Date: Mar. 8, 2007

(54) Multi-chip stack structure

(75) Inventor: Ke Chuan Yang, Taichung (TW)

Correspondence Address: EDWARDS & ANGELL, LLP, P.O. BOX 55874, BOSTON, MA, 02205, US

(73) Assignee: Siliconware Precision Industries Co., Ltd., Taichung (TW)

(21) Appl. No.: 11/485,722

(22) Filed: Jul. 12, 2006

(30) Foreign Application Priority Data
Jul. 14, 2005 (TW) 094123857

(51) Int. Cl. H01L 21/00

(52) U.S. Cl. 438/127

(57) ABSTRACT

A multi-chip stack structure includes at least one first chip having an active surface and an opposed non-active surface, wherein the active surface is formed with a plurality of connecting pads thereon; a plurality of electrical contacts formed around the first chip; an insulating layer formed on the first chip and the electrical contacts, wherein the insulating layer is formed with a plurality of openings for exposing the connecting pads and the electrical contacts; a plurality of redistributed circuit layers formed on the insulating layer, for electrically connecting the connecting pads of the first chip to the electrical contacts; at least one second chip mounted on the redistributed circuit layers and electrically connected to the redistributed circuit layers by a flip-chip or wire-bonding process; and an encapsulant formed on the second chip, the insulating layer and the redistributed circuit layers, with the electrical contacts being exposed from the encapsulant.

### FIELD OF THE INVENTION

The present invention relates to multi-chip stack structures, and more particularly, to a multi-chip stack structure without a chip carrier.

### BACKGROUND OF THE INVENTION

As profile miniaturization is becoming an important concern for a semiconductor package, a chip carrier (such as a lead frame) used in the semiconductor package and having a certain thickness is considered not favorable for reducing the overall thickness of the semiconductor package. Accordingly, a semiconductor package without a chip carrier (hereinafter referred to as “carrier-free semiconductor package”) has been developed, which desirably has a reduced thickness as compared to the conventional semiconductor packaging using the lead frame.

FIG. 1 is a cross-sectional view of a carrier-free semiconductor package disclosed in U.S. Pat. No. 5,830,800. As shown in FIG. 1, the semiconductor package is fabricated by firstly forming a plurality of pads 11 on a metallic board (not shown) according to a predetermined circuit layout, and then mounting a semiconductor chip 10 on the metallic board and performing a wire-bonding process to electrically connect the chip 10 to the pads 11 via bonding wires 12. Subsequently, an encapsulant 13 is formed to encapsulate the chip 10 and the bonding wires 12. Finally, the metallic board is etched off, such that the carrier-free semiconductor package is completed and the pads 11 are exposed. The semiconductor package can be mounted to an external printed circuit board (PCB) via the exposed pads 11 by a surface mount technology.

Although the above carrier-free semiconductor package is advantageous of having a reduced thickness, it may encounter problems such as delamination of the encapsulant or cracking of the bonding wires due to lack of a conventional lead frame. This is because the pads 11 of the carrier-free semiconductor package are only about 6 μm in thickness, which cannot be firmly held by the encapsulant 13 unlike leads of the lead frame that are about 200 μm in thickness and can be easily held by the encapsulant, such that warpage of the pads 11 and crack between the bonding wires 12 and the pads 11 are incurred. Further, delamination between the encapsulant 13 and the pads 11 may occur after implementing the surface mount technology due to insufficient adhesion between the encapsulant 13 and the pads 11.

In light of the foregoing problems, U.S. Pat. No. 6,774,499 discloses another carrier-free semiconductor package, which can prevent infirm securing of the pads and crack of the bonding wires from the pads. As shown in FIG. 2, such carrier-free semiconductor package comprises: a semiconductor chip 20 having a front surface and a back surface, wherein a plurality of connecting pads 200 are formed on the front surface; a plurality of bond pads 21 disposed on a plane substantially coplanar with the back surface of the chip 20; an insulating layer 22 for covering the chip 20 except the connecting pads 200 and the bond pads 21; a plurality of redistributed circuit layers 23 formed on the insulating layer 22, for electrically connecting the connecting pads 200 of the chip 20 to the corresponding bond pads 22; and an encapsulant 24 for covering the insulating layer 22 and the redistributed circuit layers 23, with the bond pads 21 being exposed from the encapsulant 24. The redistributed circuit layers 23 allow the chip 20 to be electrically connected to the bond pads 21 and also enhance the adhesion between the bond pads 21 and the encapsulant 24, without having to use conventional bonding wires for electrical connection such that the problem of crack of bonding wires is avoided.

In order to improve performance and functionality of a single semiconductor package, Multi-chip Module has been developed to incorporate two or more semiconductor chips in the single package, which beneficially shortens the length of circuits for interconnecting the chips, thereby reducing signal delay and access time.

Accordingly, as shown in FIG. 3, U.S. Pat. No. 6,774,499 proposes a multi-chip stacking method by which after forming a redistributed circuit layer 33 on a semiconductor chip 30 and bond pads 31, another semiconductor chip 35 is stacked on the redistributed circuit layer 33, and another redistributed circuit layer 36 is formed on the chip 35, so as to form a multi-chip stack package. However, by such method, the circuit redistribution process must be repeated when stacking each chip, thereby making the fabrication of the multi-chip stack package cost-ineffective and complicated.

### SUMMARY OF THE INVENTION

In light of the foregoing drawbacks in the prior art, a primary objective of the present invention is to provide a multi-chip stack structure for allowing a plurality of chips to be stacked by simple fabrication processes without providing a chip carrier.

Another objective of the present invention is to provide a multi-chip stack structure without a chip carrier.

A further objective of the present invention is to provide a multi-chip stack structure without a chip carrier, which can avoid crack of bonding wires.

In order to achieve the foregoing and other objectives, the present invention proposes a multi-chip stack structure comprising: at least one first chip having an active surface and an opposed non-active surface, wherein a plurality of connecting pads are formed on the active surface of the first chip; a plurality of electrical contacts formed around the first chip; an insulating layer formed on the first chip and the electrical contacts, wherein the insulating layer is formed with a plurality of openings for exposing the connecting pads of the first chip and the electrical contacts; a plurality of redistributed circuit layers formed on the insulating layer, for electrically connecting the connecting pads of the first chip to the corresponding electrical contacts; at least one second chip directly mounted on the redistributed circuit layers, the second chip being electrically connected to the redistributed circuit layers by a flip-chip or wire-bonding process; and an encapsulant formed on the second chip, the insulating layer and the redistributed circuit layers, with the electrical contacts being exposed from the encapsulant.

The multi-chip stack structure can further comprise a heat spreader mounted on a surface of the encapsulant formed on the second chip, so as to effectively dissipate heat generated by operation of the second chip to an external environment.

Therefore, the multi-chip stack structure of the present invention is formed with the redistributed circuit layers on the first chip that is not carried by a chip carrier, and allows the first chip to be electrically connected to the electrical contacts via the redistributed circuit layers instead of conventional bonding wires, such that crack between the bonding wires and pads in the prior art can be avoided. The present invention also allows the at least one second chip to be directly mounted on the redistributed circuit layers, wherein the second chip is electrically connected to the redistributed circuit layers by the flip-chip or wire-bonding process, such that the circuit redistribution process is not repeated when stacking the second chip, thereby not increasing cost and complexity of fabrication, unlike the prior art.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a schematic cross-sectional diagram of a carrier-free semiconductor package disclosed in U.S. Pat. No. 5,830,800;

FIG. 2 (PRIOR ART) is a schematic cross-sectional diagram of a carrier-free semiconductor package disclosed in U.S. Pat. No. 6,774,499;

FIG. 3 (PRIOR ART) is a schematic cross-sectional diagram of a carrier-free multi-chip stack package disclosed in U.S. Pat. No. 6,774,499;

FIG. 4 is a schematic cross-sectional diagram of a multi-chip stack structure according to a first preferred embodiment of the present invention;

FIG. 5 is a schematic cross-sectional diagram of the multi-chip stack structure according to a second preferred embodiment of the present invention;

FIG. 6 is a schematic cross-sectional diagram of the multi-chip stack structure according to a third preferred embodiment of the present invention; and

FIG. 7 is a schematic cross-sectional diagram of the multi-chip stack structure according to a fourth preferred embodiment of the present invention.

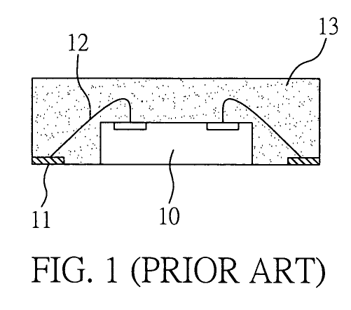

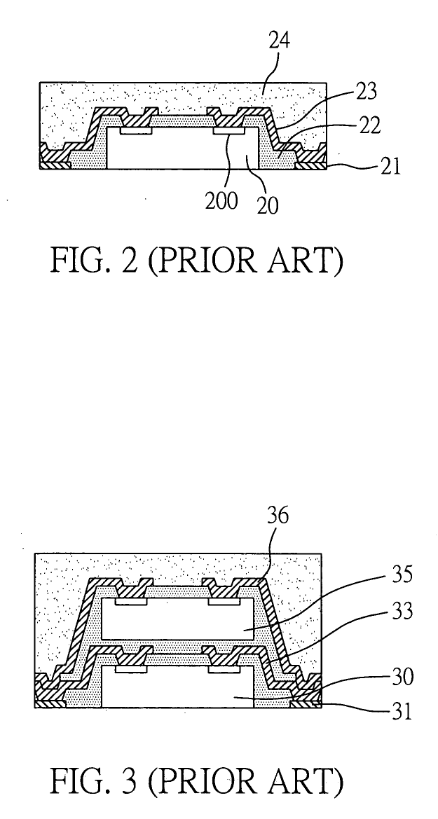

### DETAILED DESCRIPTION OF THE PREFERRED EMBODIMENTS

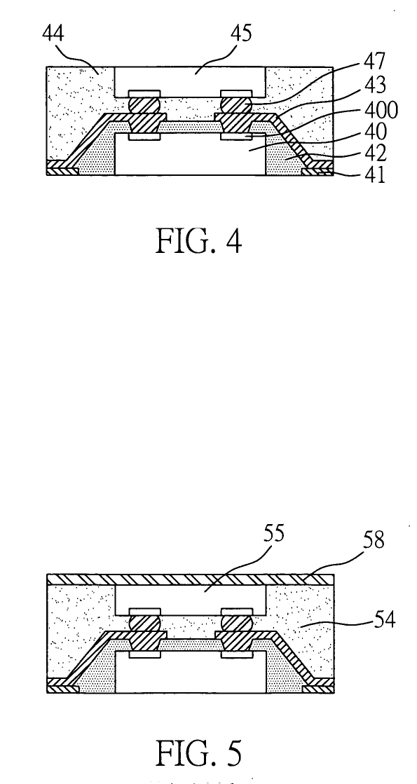

Preferred embodiments of a multi-chip stack structure proposed in the present invention are described as follows with reference to FIGS. 4-7. It should be noted that the drawings are simplified schematic diagrams only showing components relating to the present invention, and the arrangement of components could be more complex in practice.

FIG. 4 is a cross-sectional view of the multi-chip stack structure according to a first preferred embodiment of the present invention.

As shown in FIG. 4, the multi-chip stack structure comprises: at least one first chip 40 having an active surface and an opposed non-active surface, wherein a plurality of connecting pads 400 are formed on the active surface of the first chip 40; a plurality of electrical contacts 41 formed around the first chip 40; an insulating layer 42 formed on the first chip 40 and the electrical contacts 41, wherein the insulating layer 42 is formed with a plurality of openings for exposing the connecting pads 400 of the first chip 40 and the electrical contacts 41; a plurality of redistributed circuit layers 43 formed on the insulating layer 42, for electrically connecting the connecting pads 400 of the first chip 40 to the corresponding electrical contacts 41; at least one second chip 45 directly mounted on the redistributed circuit layers 43, the second chip 45 being electrically connected to the redistributed circuit layers 43 by a flip-chip process; and an encapsulant 44 formed on the second chip 45, the insulating layer 42 and the redistributed circuit layers 43, with the electrical contacts 41 being exposed from the encapsulant 44.

The electrical contacts 41 can be bond pads, metallic bumps or in the form of other structures. The electrical contacts 41 can be made of solder, palladium or gold, etc.

The first chip 40 has the active surface and the non-active surface. The plurality of connecting pads 400 are formed on the active surface of the first chip 40 and serve as electrical input/output (I/O) connections. The non-active surface of the first chip 40 is exposed from the encapsulant 44.

The insulating layer 42 can be made of an insulating material such as polyimide (PI) or benzocyclobutene (BCB). The insulating layer 42 can be subjected to a lithography technique to partially remove the insulating layer 42 and form the openings thereof for exposing the connecting pads 400 of the first chip 40 and the electrical contacts 41.

The redistributed circuit layers 43 are formed on the insulating layer 42, and are used to electrically connect the connecting pads 400 of the first chip 40 to the electrical contacts 41.

The second chip 45 has an active surface and an opposed non-active surface. The second chip 45 is electrically connected to the redistributed circuit layers 43 in a flip-chip manner via metallic bumps (solder bumps) 47 formed on the active surface of the second chip 45.

The encapsulant 44 covers the second chip 45, the redistributed layers 43 and the insulating layer 42 to avoid any external contaminants entering the multi-chip stack structure. Further, the encapsulant 44 can be subjected to a thinning process, so as to allow the non-active surface of the second chip 45 to be exposed from the encapsulant 44, such that heat generated by operation of the second chip 45 can be dissipated via the exposed non-active surface thereof to an external environment.

Therefore, the multi-chip stack structure of the present invention is formed with the redistributed circuit layers on the first chip that is not carried by a chip carrier, and allows the first chip to be electrically connected to the electrical contacts via the redistributed circuit layers instead of conventional bonding wires, such that crack between the bonding wires and pads in the prior art can be avoided. The present invention also allows the at least one second chip to be directly mounted on the redistributed circuit layers, wherein the second chip is electrically connected to the redistributed circuit layers by the flip-chip process, such that the circuit redistribution process is not repeated when stacking the second chip, thereby not increasing cost and complexity of fabrication, unlike the prior art.

FIG. 5 is a cross-sectional view of the multi-chip stack structure according to a second preferred embodiment of the present invention. The multi-chip stack structure of the second embodiment is similar to that of the foregoing first embodiment, with a primary difference in that a heat spreader 58 is further provided for the multi-chip stack structure in the second embodiment. With the non-active surface of the second chip 55 being exposed from the encapsulant 54, the heat spreader 58 is attached to the exposed non-active surface of the second chip 55, such that heat generated by operation of the second chip 55 can be directly dissipated through the heat spreader 58 to the external environment.

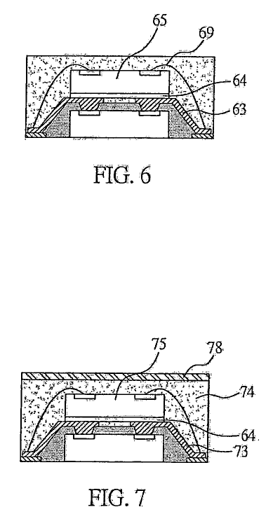

FIG. 6 is a cross-sectional view of the multi-chip stack structure according to a third embodiment of the present invention. The multi-chip stack structure of the third embodiment is similar to that of the foregoing first embodiment, with a primary difference in that the second chip 65 can be attached to the redistributed circuit layers 63 via an adhesive layer 64 and is electrically connected to the redistributed circuit layers 63 by bonding wires 69 in the third embodiment.

FIG. 7 is a cross-sectional view of the multi-chip stack structure according to a fourth embodiment of the present invention. The multi-chip stack structure of the fourth embodiment is similar to that of the above third embodiment, with a primary difference in that the multi-chip stack structure further comprises a heat spreader 78 in the fourth embodiment, wherein the heat spreader 78 is attached to a surface of the encapsulant 74 formed on the second chip 75, such that heat generated by operation of the second chip 75 that is attached to the redistributed circuit layers 73 via the adhesive layer 64 can be dissipated through the heat spreader 78 to the external environment.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A multi-chip stack structure comprising:
at least one first chip having an active surface and an opposed non-active surface, wherein the active surface is formed with a plurality of connecting pads thereon;
a plurality of electrical contacts formed around the first chip;
an insulating layer formed on the first chip and the electrical contacts, wherein the insulating layer is formed with a plurality of openings for exposing the connecting pads of the first chip and the electrical contacts;
a plurality of redistributed circuit layers formed on the insulating layer, for electrically connecting the connecting pads of the first chip to the electrical contacts;
at least one second chip directly mounted on the redistributed circuit layers, the second chip being electrically connected to the redistributed circuit layers in one of a flip-chip manner and a wire-bonding manner; and
an encapsulant formed on the second chip, the insulating layer and the redistributed circuit layers, with the electrical contacts being exposed from the encapsulant.

2. The multi-chip stack structure of claim 1, further comprising a heat spreader attached to a surface of the encapsulant formed on the second chip.

3. The multi-chip stack structure of claim 1, wherein the second chip has an active surface and an opposed non-active surface, allowing the active surface of the second chip to be electrically connected to the redistributed circuit layers in the flip-chip manner, and allowing the non-active surface of the second chip to be exposed from the encapsulant.

4. The multi-chip stack structure of claim 3, further comprising a heat spreader attached to the non-active surface of the second chip.

5. The multi-chip stack structure of claim 1, wherein the second chip has an active surface and an opposed non-active surface, allowing the non-active surface of the second chip to be attached to the redistributed circuit layers, and allowing the active surface of the second chip to be electrically connected to the redistributed circuit layers via bonding wires.

6. The multi-chip stack structure of claim 1, wherein each of the electrical contacts is one of a bond pad and a metallic bump.

7. The multi-chip stack structure of claim 1, wherein the insulating layer is made of one of polyimide (PI) and benzocyclobutene (BCB).
